(19) United States
(12) Patent Application Publication
(10) Pub. No.: US 2014/0273792 A1
(43) Pub. Date: Sep. 18, 2014

(54) CONTAINER-TYPE DATA CENTER AND METHOD FOR CONTROLLING CONTAINER-TYPE DATA CENTER

(71) Applicant: FUJITSU LIMITED, Kawasaki-shi (JP)

(72) Inventor: Reiko KONDO, Yamato (JP)

(73) Assignee: FUJITSU LIMITED, Kawasaki-shi (JP)

(21) Appl. No.: 14/100,165

(22) Filed: Dec. 9, 2013

(30) Foreign Application Priority Data
Mar. 18, 2013 (JP) 2013-055648

(51) Int. Cl. H05K 7/20

(52) U.S. Cl. CPC H05K 7/20709
USPC 454/184

(57) ABSTRACT

A container includes a server mounted therein and separates a cold aisle from a hot aisle. A shutter opens and closes an opening provided in the cold aisle and communicating with the outside. Another shutter opens and closes an opening provided in the hot aisle and communicating with the outside. An air conditioner cools air taken in from the cold aisle and exhausts the air to the hot aisle. A management server controls opening and closing of the shutters based on any of an acquired pressure in the cold aisle and an operating state of the air conditioner.

### CROSS-REFERENCE TO RELATED APPLICATION

This application is based upon and claims the benefit of priority of the prior Japanese Patent Application No. 2013-055648, filed on Mar. 18, 2013, the entire contents of which are incorporated herein by reference.

### FIELD

The embodiments discussed herein are related to a container-type data center and a method for controlling the container-type data center.

### BACKGROUND

Examples of data centers include facilities that centrally install and operate a large amount of hardware including servers as information processing devices and electronic equipment such as communication equipment. In recent years, cloud services have been developed, and a scale of the data center continues growing. Large-scale data centers require more power saving.

To construct such a large-scale data center, a container-type data center has been developed that involves low initial investment cost. In the container-type data center, a small space in the container is defined as one unit, and information equipment and an air conditioner are mounted in the unit to operate and cool the information equipment on a unit basis. That is, the container type data center is a portable-type data center that can be easily expanded according to a scale of the entire data center and is an effective form for reducing total power consumption and achieving power saving, whereby the container-type data center has been rapidly spread.

Examples of equipment installed in such a container-type data center include a network device, a storage device, and an electronic computer such as a server. Some pieces of the equipment arranged in the data center includes a heat generation component such as a central processing unit (CPU) as an arithmetic processing unit or a main memory as a main storage device. When temperatures of these components increase, the air conditioner lowers the temperatures of the components. This also lowers the temperature in the container.

As a configuration of the container-type data center, known is a configuration in which a cold aisle and a hot aisle are separated, cold air from the air conditioner is effectively sent to an intake side of the server, and hot air from the hot aisle is prevented from flowing to the intake side of the server.

In a case in which pressure is unbalanced in the container-type data center having the air conditioner, problems as described below arise. For example, excessively high pressure in the cold aisle results in excessive power for carrying air. It also decreases the temperature of the air returned to the air conditioner, so that the air conditioner operates in an inefficient operation range. In contrast, excessively low pressure in the cold aisle reduces air supply volume to the server, so that the temperature of the server increases. In the container-type data center having the air conditioner, therefore, pressure balance in the entire container is maintained by adjusting the volume of air from a fan of the air conditioner and the volume of air from a fan of the server and the like.

As a technique for controlling the air conditioner in the data center, there is a conventional technique for controlling the volume of air so that the volume of air from the cold aisle to the hot aisle is equal to the volume of air from the hot aisle to the air conditioner (for example, refer to Japanese Laid-open Patent Publication No. 2010-43817). There is also a conventional technique for adjusting the volume of air from the air conditioner according to a mode of a compressor of the air conditioner (for example, refer to Japanese Laid-open Patent Publication No. 2011-85267). There is also a conventional technique of using a door for a server room separate the cold aisle and the hot aisle (for example, refer to Japanese Laid-open Patent Publication No. 2011-243051).

However, in the container-type data center, the number of the servers to be mounted depends on operation forms, such as a case in which the maximum number of servers are mounted in the container, a case in which only one server is mounted therein, and the like. In the container-type data center, the volume of air for cooling differs according to the number of the servers. Therefore, it is difficult to appropriately maintain the pressure balance of the entire container using the air conditioner.

In a conventional technique in which the volume of air from a cool zone to a hot zone is equal to the volume of air from the hot zone to the air conditioner, it is difficult to appropriately maintain the pressure balance when the air conditioner breaks down or when the number of servers is small relative to the volume of air from the air conditioner. Even a technique for controlling the air conditioner according to the mode of the compressor does not work when the air conditioner breaks down, so that it is difficult to appropriately maintain the pressure balance. In a technique using the door for a server room to separate the cold aisle and the hot aisle, the pressure in each aisle is not taken into consideration, so that it is difficult to appropriately maintain the pressure balance.

### SUMMARY

According to an aspect of an embodiment, a container-type data center includes: a container that includes electronic equipment mounted therein and separates a first area as an intake side of the electronic equipment from a second area as an exhaust side of the electronic equipment; a first shutter that opens and closes an opening connecting outside and inside of the container provided in the first area; a second shutter that opens and closes an opening connecting outside and inside of the container provided in the second area; an air conditioning mechanism that cools air taken in from the second area and exhausts the air to the first area; and a control unit that controls opening and closing of the first shutter and the second shutter based on an acquired pressure in the first area or an operating state of the air conditioning mechanism.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a perspective view illustrating part of a container-type data center;

FIG. 1B is a perspective view illustrating part of the container-type data center, viewed from another direction;

FIG. 2 is a schematic cross-sectional view of the container-type data center according to a first embodiment;

FIG. 3A is a diagram for illustrating a rotary-type shutter;

FIG. 3B is a diagram for illustrating a slide-type shutter;

FIG. 4 is a block diagram of the container-type data center according to the first embodiment;

FIG. 5 is a flow chart of a process for adjusting pressure with the container-type data center according to the first embodiment;

FIG. 6 is a diagram illustrating a measurement area of an intake air temperature;

FIG. 7A is a graph of the temporal change of a server intake air temperature after an air conditioner has stopped in a conventional container-type data center;

FIG. 7B is a graph of the temporal change of the server intake air temperature after an air conditioner has stopped in the container-type data center according to the first embodiment;

FIG. 8 is a graph of an average server intake air temperature after one minute, against the number of openings;

FIG. 9 is a diagram illustrating a relation among an opening ratio, the height of the opening, and the average server intake air temperature;

FIG. 10 is a schematic cross-sectional view of a container-type data center according to a second embodiment;

FIG. 11 is a block diagram of the container-type data center according to the second embodiment;

FIG. 12 is a flow chart of a process for adjusting pressure with the container-type data center according to the second embodiment;

FIG. 13 is a schematic cross-sectional view of a container-type data center according to a third embodiment;

FIG. 14 is a diagram illustrating an operation of a pressure-regulating valve;

FIG. 15A is a diagram illustrating a closed state of an example of the pressure-regulating valve;

FIG. 15B is a diagram illustrating an open state of the example of the pressure-regulating valve;

FIG. 16A is a diagram illustrating a closed state of another example of the pressure-regulating valve;

FIG. 16B is a diagram illustrating an open state of the example of the pressure-regulating valve;

FIG. 17A is a diagram illustrating a closed state of an example of the pressure-regulating valve, having a double-doored configuration;

FIG. 17B is a diagram illustrating an open state of the example of the pressure-regulating valve, having the double-doored configuration;

FIG. 18 is a block diagram of a container-type data center according to a modification of the third embodiment;

FIG. 19 is a flow chart of a process for adjusting pressure with the container-type data center according to the modification of the third embodiment; and

FIG. 20 is a schematic cross-sectional view of a container-type data center according to a fourth embodiment.

### DESCRIPTION OF EMBODIMENTS

Preferred embodiments of the present invention will be explained with reference to accompanying drawings. The container-type data center and the method for controlling the container-type data center disclosed herein are not limited by the embodiments described below.

### [a] First Embodiment

FIG. 1A is a perspective view illustrating part of the container-type data center. FIG. 1B is a perspective view illustrating part of the container-type data center, viewed from another direction. A container-type data center 100 illustrated in FIG. 1A and FIG. 1B is a cut-out part of the actual container-type data center. That is, the actual container-type data center has a plurality of container-type data centers 100 arranged.

The container-type data center 100 includes a container 5, an air conditioner 3, and a duct 4 that sends air from the container 5 to the air conditioner 3. The container 5 has a rack 2 installed. The rack 2 is mounted with one or more servers 1. The container 5 includes an opening 6 and an opening 7 that connect the inside and the outside of the container 5. Although not illustrated in FIG. 1A and FIG. 1B for convenience of description, the container-type data center 100 according to a first embodiment has shutters provided on the opening 6 and the opening 7. The shutters will be described in detail below.

FIG. 2 is a schematic cross-sectional view of the container-type data center according to the first embodiment. As illustrated in FIG. 2, the server 1 illustrated in FIG. 1A and FIG. 1B includes a management server 10 and a server 11. The management server 10 manages the air conditioner, controls the shutters, and manages the server 11. The server 11 is a server that executes processing. Although the number of the management servers 10 is not specifically limited, the present embodiment describes a case with one management servers 10. All servers other than the management server 10 in FIG. 2 are the servers 11. For convenience of description, FIG. 2 does not illustrate the rack 2 mounted with the management server 10 and the servers 11.

The inside of the container 5 is divided into two regions, a cold aisle 51 and a hot aisle 52, with the rack 2 mounted with the management server 10 and the servers 11 and a partition plate extending from the rack 2 to an inner wall of the container 5. The cold aisle 51 is connected to the air conditioner 3 and is supplied with air cooled by the air conditioner 3. The air supplied from the air conditioner 3 causes air in the cold aisle 51 to flow to the rack 2 mounted with the management server 10 and the servers 11 to cool the management server 10 and the servers 11. The heated air is supplied to the hot aisle 52 connected to the duct 4. The heated air in the hot aisle 52 is supplied to the air conditioner 3 through the duct 4.

The opening 6, provided on a wall on the cold aisle 51 side of the container 5, has a shutter 60 attached. The shutter 60 is openable. The shutter 60 closed blocks an airflow between the cold aisle 51 and the outside of the container 5. The shutter 60 opened allows the airflow between the cold aisle 51 and the outside of the container 5.

The opening 7, provided on a wall on the hot aisle 52 side of the container 5, has a shutter 70 attached. The shutter 70 is openable. The shutter 70 closed blocks an airflow between the hot aisle 52 and the outside of the container 5. The shutter 70 opened allows the airflow between the hot aisle 52 and the outside of the container 5.

The shutter 60 and the shutter 70 are connected to the management server 10. The shutter 60 and the shutter 70 open or close according to an instruction from the management server 10. The shutter 60 and the shutter 70 may have the same structure or may have different structures.

With reference to FIG. 3A and FIG. 3B, an example of the structure of the shutter 60 and the shutter 70 will be described. FIG. 3A is a diagram for illustrating a rotary-type shutter. FIG. 3B is a diagram for illustrating a slide-type shutter. FIG. 3A and FIG. 3B take the shutter 70 as an example.

In a case of the rotary-type shutter illustrated in FIG. 3A, the shutter 70 includes a plurality of rotatable plate members 71. The plate members 71 rotate in a direction represented by an arrow P1. A state of the plate members 71 illustrated with a solid line is a state in which the shutter 70 is open. A state of plate members 72 illustrated with a dotted line is a state in which the shutter 70 is closed. A filter 73 is provided so that dust does not enter the inside of the container 5 in the state in which the shutter 70 is open.

In a case of the slide-type shutter illustrated in FIG. 3B, the shutter 70 includes a plurality of slidable plate members 74. The plate members 74 slide in a direction represented by an arrow P2. A state of the plate members 74 illustrated with a solid line is a state in which the shutter 70 is open. A state of plate members 75 illustrated with a dotted line is a state in which the shutter 70 is nearly closed.

The air conditioner 3 includes a fan 30 (refer to FIG. 2). The air conditioner 3 rotates the fan 30 and takes in air sent from the hot aisle 52 through the duct 4 to cool the air. Then the air conditioner 3 supplies the cooled air to the cold aisle 51 through rotation of the fan 30.

A pressure sensor 8 is provided inside the cold aisle 51. The pressure sensor 8 measures pressure inside the cold aisle 51. The pressure sensor 8 is connected to the management server 10 and transmits information about the measured pressure to the management server 10.

The following describes a function of controlling opening and closing of the shutter 60 and the shutter 70 in the container-type data center 100 according to the present embodiment with reference to FIG. 4. FIG. 4 is a block diagram of the container-type data center according to the first embodiment.

The management server 10 includes a state monitoring unit 101 and a shutter control unit 102.

For example, the state monitoring unit 101 monitors an operation of the air conditioner 3, such as the rotational speed of the fan 30. Then the state monitoring unit 101 determines whether the air conditioner 3 has stopped. For example, the state monitoring unit 101 determines that the air conditioner 3 has stopped, from the fact that the rotation of the fan 30 has stopped. Having determined that the air conditioner 3 has stopped, the state monitoring unit 101 notifies the shutter control unit 102 that the air conditioner 3 has stopped.

After the air conditioner 3 has stopped, the state monitoring unit 101 continues to monitor the operation of the air conditioner 3. If the air conditioner 3 has resumed, the state monitoring unit 101 notifies the shutter control unit 102 of the resumption of the air conditioner 3.

If the air conditioner 3 has stopped, the shutter control unit 102 receives a notification that the air conditioner 3 has stopped from the state monitoring unit 101. Having received the notification that the air conditioner 3 has stopped, the shutter control unit 102 opens the shutter 60 and the shutter 70.

After that, upon receiving a notification of the resumption of the air conditioner 3 from the state monitoring unit 101, the shutter control unit 102 closes the shutter 60 and the shutter 70.

In the present embodiment, the shutter control unit 102 stores therein standard pressure as an atmospheric pressure. The shutter control unit 102 receives an input of information about the pressure in the cold aisle 51 from the pressure sensor 8. Then the shutter control unit 102 compares the received pressure in the cold aisle 51 with the stored atmospheric pressure. If the pressure in the cold aisle 51 is less than the atmospheric pressure, the shutter control unit 102 opens the shutter 60 and the shutter 70.

The air conditioner 3 may stop because of a power failure or a breakdown. For example, in a case of the power failure, although the server 1 continues to operate with an uninterruptible power supply unit and the like, the air conditioner 3 stops. Accordingly, the pressure in the cold aisle 51 abruptly drops, and a sufficient volume of air is not supplied to the server 1. In addition, a hot air in the hot aisle 52 is routed to the cold aisle 51 via the duct 4 and the air conditioner 3, so that the server 1 takes in the hot air. Accordingly, the temperature of the server 1 increases, which breaks down or stops the server 1. Therefore, the shutter control unit 102 opens the shutter 60 and the shutter 70 to increase the pressure in the cold aisle 51, secure the volume of air to the server 1, and lower the intake air temperature of the server 1.

After that, the shutter control unit 102 continues to compare the received pressure in the cold aisle 51 with the stored atmospheric pressure. If the pressure in the cold aisle 51 has become equal to or more than the atmospheric pressure, the shutter control unit 102 closes the shutter 60 and the shutter 70.

In the present embodiment, the shutter control unit 102 stores therein the atmospheric pressure in advance. Alternatively, for example, a sensor for measuring an outside air pressure may be provided to the outside of the container 5, and the outside air pressure acquired by the sensor may be used as the atmospheric pressure.

The following describes the procedure of a process for adjusting pressure with the container-type data center 100 according to the present embodiment with reference to FIG. 5. FIG. 5 is a flow chart of the process for adjusting pressure with the container-type data center according to the first embodiment. The process described below is the procedure of one process for adjusting pressure. Practically, the shutter control unit 102 periodically repeats the procedure of the process.

The shutter control unit 102 determines whether the air conditioner 3 has stopped based on a notification from the state monitoring unit 101 (Step S101). If the air conditioner 3 has stopped (Yes at Step S101), the shutter control unit 102 opens the shutter 60 and the shutter 70 (Step S102).

After that, the shutter control unit 102 determines whether the air conditioner 3 has resumed based on a notification from the state monitoring unit 101 (Step S103). If the air conditioner 3 has not resumed (No at Step S103), the shutter control unit 102 waits until the air conditioner 3 resumes.

If the air conditioner 3 has resumed (Yes at Step S103), the shutter control unit 102 closes the shutter 60 and the shutter 70 (Step S107).

If the air conditioner has not stopped (No at Step S101), the shutter control unit 102 determines whether the pressure in the cold aisle 51 is less than the atmospheric pressure (Step S104). If the pressure in the cold aisle 51 is equal to or more than the atmospheric pressure (No at Step S104), the shutter control unit 102 finishes the process for adjusting pressure.

If the pressure in the cold aisle 51 is less than the atmospheric pressure (Yes at Step S104), the shutter control unit 102 opens the shutter 60 and the shutter 70 (Step S105).

After that, the shutter control unit 102 determines whether the pressure in the cold aisle 51 is equal to or more than the atmospheric pressure (Step S106). If the pressure in the cold aisle 51 is less than the atmospheric pressure (No at Step S106), the shutter control unit 102 waits until the pressure in the cold aisle 51 becomes equal to or more than the atmospheric pressure.

If the pressure in the cold aisle 51 is equal to or more than the atmospheric pressure (Yes at Step S106), the shutter control unit 102 closes the shutter 60 and the shutter 70 (Step S107).

The following describes an effect of using the container-type data center 100 according to the present embodiment. Hereinafter, described is a calculation result of the intake air temperature of the server under conditions described below. The conditions includes a configuration illustrated in FIG. 1A and FIG. 1B, in which two racks 2 and one air conditioner 3 are disposed. The racks 2 each are mounted with eighty servers 1. Considering the thickness of a housing of the server 1 and the thickness of the rack 2, metal materials are set for them, respectively. Assuming that the width of the opening 6 is 1 m and the height thereof is 450 mm, and the width of the opening 7 is 1 m and the height thereof is 60 cm. With a filter or a louver to be provided to the opening 6 and the opening 7 taken into account, a pressure loss is equivalent to the opening ratio of 60%.

FIG. 6 is a diagram illustrating a measurement area of the intake air temperature. Hereinafter, described is a simulation result of the temporal change of the intake air temperature in each of areas 201 to 204 and 211 to 214 of the rack 2 illustrated in FIG. 6 in the container-type data center 100. The maximum number of servers, including the management server 10 and the servers 11, are mounted in the rack 2. Each of the areas 201 to 204 and 211 to 214 is an area where measurements are averaged over 10 each of the management server 10 and the servers 11 mounted in the rack 2.

FIG. 7A is a graph of the temporal change of the server intake air temperature after the air conditioner has stopped in a conventional container-type data center. FIG. 7B is a graph of the temporal change of the server intake air temperature after an air conditioner has stopped in the container-type data center according to the first embodiment. In each of FIG. 7A and FIG. 7B, a vertical axis represents the server intake air temperature and a horizontal axis represents time. A dotted line in FIG. 7A and FIG. 7B represents guaranteed operating temperature of the server 11. For example, the guaranteed operating temperature in the present embodiment is 35° C. In FIG. 7A and FIG. 7B, described is a case in which environmental temperature (outside temperature) is 30° C.

As illustrated in FIG. 7A, in the conventional container-type data center, the intake air temperature of the server 11 in any of the areas 201 to 204 and 211 to 214 exceeds 35° C., which is the guaranteed operating temperature of the server 11, in about ten seconds. Therefore, the conventional container-type data center has an increased risk that the server 11 breaks down.

In contrast, as illustrated in FIG. 7B, in the container-type data center 100 according to the present embodiment, the intake air temperature of the server 11 in most of the areas 201 to 204 and 211 to 214 is equal to or less than 35° C., which is the guaranteed operating temperature of the server 11, when two minutes or more have elapsed after the air conditioner has stopped. Accordingly, as compared with the conventional container-type data center, the container-type data center 100 according to the present embodiment has an increase probability of avoiding a breakdown of the server 11. These days an increasing number of servers have a guaranteed operating temperature of 40° C. When such a server is used as the server 11, the server 11 can normally operate at the guaranteed operating temperature or less even if the air conditioner has stopped.

With reference to FIG. 8, an effect of the opening 6 and the opening 7 will be described. FIG. 8 is a graph of an average server intake air temperature after one minute, against the number of openings. In FIG. 8, a vertical axis represents the average server intake air temperature and a horizontal axis represents various states of the opening. A right bar graph in each of the states corresponds to a case of the environmental temperature of 40° C., and a left bar graph corresponds to a case of the environmental temperature of 30° C. A dotted line in FIG. 8 represents the guaranteed operating temperature of the server 11, which is 35° C.

When the opening 6 and the opening 7 are not provided, the server intake air temperature after one minute exceeds 52° C. in both cases with the environmental temperatures of 30° C. and 40° C. The server intake air temperature significantly exceeds the guaranteed operating temperature of the server 11, whereby it is highly possible that the server 11 breaks down.

In a case with the opening 6 only, the server intake air temperature after one minute is lower than in a case without the opening 6 or the opening 7, but still exceeds 50° C. In this case too, the server intake air temperature significantly exceeds the guaranteed operating temperature of the server 11, whereby it is highly possible that the server 11 breaks down.

In contrast, when the opening 6 and the opening 7 are provided, the server intake air temperature after one minute falls below 35° C., which is the guaranteed operating temperature, at the environmental temperature of 30° C. In a case of the environmental temperature of 40° C., the server intake air temperature after one minute decreases to about 42° C., greatly reducing the risk of breakdown of the server 11 having the guaranteed operating temperature of 40° C. As described above, the opening 6 on the cold aisle 51 side and the opening 7 on the hot aisle 52 side significantly reduce the intake air temperature of the server 11 as compared to a case with only the opening 6 on the cold aisle 51 side.

With reference to FIG. 9, a preferred shape and opening ratio of the opening will be described. FIG. 9 is a diagram illustrating a relation among the opening ratio, the height of the opening, and the average server intake air temperature. In FIG. 9, a vertical axis represents the average server intake air temperature, an upper horizontal axis represents the opening ratio, and a lower horizontal axis represents the height of the opening 7. A graph 301 represents change in the average server intake air temperature for different opening ratios of the opening 6 and the opening 7 provided, when the width of the opening 7 is 1 m and the height thereof is 60 cm. A graph 302 represents change in the average server intake air temperature for different heights of the opening 7 provided, when the opening ratios of the opening 6 provided and the opening 7 are both 60% and the widths thereof are both 1 m.

As illustrated by the graph 302, if the height of the opening 7 is 250 mm or more, the average server intake air temperature falls below 35° C., which is the guaranteed operating temperature. As illustrated by the graph 301, if the opening ratios of the opening 6 and the opening 7 are 50% or more, the average server intake air temperature falls below 35° C., which is the guaranteed operating temperature. A filter or a louver provided to the opening 7 generates the pressure loss and changes the opening ratio. Specifically, when the pressure loss is 60% and the width of the opening 7 is 1 m, the height of the opening 7 is preferably 250 mm or more. In a case in which the opening 6 and the opening 7 are provided, the width of the opening 6 is 1 m and the height thereof is 450 mm, and the width of the opening 7 is 1 m and the height thereof is 60 cm, it is preferable that the opening ratios of the opening 6 and the opening 7 are both 50% or more despite the influence of the pressure loss when a filter or a louver is provided.

As described above, in the container-type data center according to the present embodiment, the opening communicating from the container to the outside is opened when the air conditioner has stopped or when the pressure in the cold aisle has become lower than the atmospheric pressure. This prevents a heated air from the hot aisle side from entering the cold aisle side. This also increases the pressure in the cold aisle and the pressure balance can be appropriately maintained. Consequently, the server can be appropriately cooled by reducing an increase in the server temperature due to a pressure drop in the cold aisle or the stoppage of the air conditioner.

### [b] Second Embodiment

FIG. 10 is a schematic cross-sectional view of a container-type data center according to a second embodiment. The container-type data center 100 according to the present embodiment is different from that in the first embodiment in that the volume of air from the air conditioner is reduced when the pressure in the cold aisle is higher than the atmospheric pressure. Hereinafter, adjustment of the volume of air from the air conditioner will be mainly described. FIG. 11 is a block diagram of the container-type data center according to the second embodiment. In FIG. 11, each component having the same reference numeral as that in FIG. 4 has the same function unless described otherwise.

As illustrated in FIG. 10, in the container-type data center 100 according to the present embodiment, the management server 10 and the fan 30 are connected. FIG. 10 is merely a conceptual diagram, which means that the management server 10 is not necessarily directly connected with the fan 30 so long as they are connected to allow the management server 10 to control the volume of air from the fan 30.

As illustrated in FIG. 11, the management server 10 includes an air volume control unit 103. For example, the air volume control unit 103 stores therein standard pressure as the atmospheric pressure.

The air volume control unit 103 receives an input of information about the pressure in the cold aisle 51 from the pressure sensor 8. Next, the air volume control unit 103 determines whether the pressure in the cold aisle 51 is higher than the stored atmospheric pressure. If the pressure in the cold aisle 51 is higher than the atmospheric pressure, the air volume control unit 103 reduces the rotational speed of the fan 30 to lower the volume of air sent from the air conditioner 3.

After that, when the pressure in the cold aisle 51 has become equal to or less than the atmospheric pressure, the air volume control unit 103 restores the rotational speed of the fan 30 to increase the volume of air sent from the air conditioner 3.

The following describes the procedure of a process for adjusting pressure with the container-type data center 100 according to the present embodiment with reference to FIG. 12. FIG. 12 is a flow chart of the process for adjusting pressure with the container-type data center according to the second embodiment. The process described below is the procedure of one process for adjusting pressure. Practically, the management server 10 periodically repeats the procedure of the process.

The shutter control unit 102 determines whether the air conditioner 3 has stopped based on a notification from the state monitoring unit 101 (Step S201). If the air conditioner 3 has stopped (Yes at Step S201), the shutter control unit 102 opens the shutter 60 and the shutter 70 (Step S202).

After that, the shutter control unit 102 determines whether the air conditioner 3 has resumed based on a notification from the state monitoring unit 101 (Step S203). If the air conditioner 3 has not resumed (No at Step S203), the shutter control unit 102 waits until the air conditioner 3 resumes.

If the air conditioner 3 has resumed (Yes at Step S203), the shutter control unit 102 closes the shutter 60 and the shutter 70 (Step S207).

If the air conditioner has not stopped (No at Step S201), the shutter control unit 102 determines whether the pressure in the cold aisle 51 is less than the atmospheric pressure (Step S204).

If the pressure in the cold aisle 51 is less than the atmospheric pressure (Yes at Step S204), the shutter control unit 102 opens the shutter 60 and the shutter 70 (Step S205).

After that, the shutter control unit 102 determines whether the pressure in the cold aisle 51 is equal to or more than the atmospheric pressure (Step S206). If the pressure in the cold aisle 51 is less than the atmospheric pressure (No at Step S206), the shutter control unit 102 waits until the pressure in the cold aisle 51 becomes equal to or more than the atmospheric pressure.

If the pressure in the cold aisle 51 is equal to or more than the atmospheric pressure (Yes at Step S206), the shutter control unit 102 closes the shutter 60 and the shutter 70 (Step S207).

If the pressure in the cold aisle 51 is equal to or more than the atmospheric pressure (No at Step S204), the air volume control unit 103 determines whether the pressure in the cold aisle 51 is higher than the atmospheric pressure (Step S208). If the pressure in the cold aisle 51 is equal to or less than the atmospheric pressure (No at Step S208), the management server 10 finishes the process for adjusting the pressure.

If the pressure in the cold aisle 51 is higher than the atmospheric pressure (Yes at Step S208), the air volume control unit 103 reduces the rotational speed of the fan 30 (Step S209).

After that, the air volume control unit 103 determines whether the pressure in the cold aisle 51 has become equal to or less than the atmospheric pressure (Step S210). If the pressure in the cold aisle 51 is higher than the atmospheric pressure (No at Step S210), the air volume control unit 103 reduces the rotational speed of the fan until the pressure in the cold aisle 51 becomes equal to or less than the atmospheric pressure.

If the pressure in the cold aisle 51 is equal to or less than the atmospheric pressure (Yes at Step S210), the air volume control unit 103 restores the rotation of the fan 30 (Step S211).

As described above, the container-type data center according to the present embodiment operates to lower the volume of air from the air conditioner when the pressure in the cold aisle has increased, in addition to the opening and closing of the shutters in the first embodiment. This reduces the pressure in the cold aisle when the pressure in the cold aisle is high, and the pressure balance can be more appropriately maintained.

### [c] Third Embodiment

FIG. 13 is a schematic cross-sectional view of a container-type data center according to a third embodiment. The container-type data center 100 according to the present embodiment is different from that in the first embodiment in that a path connecting the cold aisle and the hot aisle is opened when the pressure in the cold aisle is higher than the pressure in the hot aisle. Hereinafter, the opening and closing of the path connecting the cold aisle and the hot aisle will be mainly described.

As illustrated in FIG. 13, in the container-type data center 100 according to the present embodiment, a part in the rack to which the management server 10 or the server 11 is not mounted serves as a path connecting the cold aisle 51 and the hot aisle 52. On a front side of the part in the rack to which the management server 10 or the server 11 is not mounted, a pressure-regulating valve 9 is provided.

FIG. 14 is a diagram illustrating an operation of the pressure-regulating valve. In FIG. 14, the right side of the pressure-regulating valve 9 is the cold aisle 51 side. The left side of the pressure-regulating valve 9 communicates with the hot aisle 52.

For example, the pressure-regulating valve 9 is provided to a blank panel arranged in the part of the rack to which the server is not mounted. The pressure-regulating valve 9 is rotatably arranged to open toward the hot aisle 52 side. When there is no difference between the pressure in the cold aisle 51 and the pressure in the hot aisle 52, the pressure-regulating valve 9 is in a position represented by a dotted line in FIG. 14.

If the pressure in the cold aisle 51 is higher than the pressure in the hot aisle 52 enough to move the pressure-regulating valve 9, the pressure-regulating valve 9 opens toward the hot aisle 52 side. Accordingly, the air on the cold aisle 51 side flows into the hot aisle 52, so that there is no difference between the pressure in the cold aisle 51 and the pressure in the hot aisle 52.

When there is no difference between the pressure in the cold aisle 51 and the pressure in the hot aisle 52, the pressure-regulating valve 9 returns to the position represented by the dotted line in FIG. 14 owing to its own weight and the like, and blocks the path connecting the cold aisle 51 and the hot aisle 52.

FIG. 15A is a diagram illustrating a closed state of an example of the pressure-regulating valve. FIG. 15B is a diagram illustrating an open state of the example of the pressure-regulating valve.

For example, as illustrated in FIG. 15A, the entire surface of the blank panel works as the pressure-regulating valve 9. That is, the pressure-regulating valve 9 has a width extending from the left end to the right end of the rack 2. The pressure-regulating valve 9 has a height equal to the length between the upper server 11 and the lower server 11. In this case, when the pressure in the cold aisle 51 is higher than the pressure in the hot aisle 52, the entire surface of the blank panel, which works as the pressure-regulating valve 9, rotates as illustrated in FIG. 15B.

FIG. 16A is a diagram illustrating a closed state of another example of the pressure-regulating valve. FIG. 16B is a diagram illustrating an open state of the example of the pressure-regulating valve.

For example, as illustrated in FIG. 16A, part of a blank panel 92 works as the pressure-regulating valve 9. In this case, the remaining part of the blank panel 92 surrounds the pressure-regulating valve 9. That is, the pressure-regulating valve 9 in this case has a width extending from a position at a predetermined distance from the left end of the rack 2 to a position at a predetermined distance from the right end of the rack 2. The pressure-regulating valve 9 has a height smaller than the length between the upper server 11 and the lower server 11. In this case, when the pressure in the cold aisle 51 is higher than the pressure in the hot aisle 52, the part of the blank panel 92, which works as the pressure-regulating valve 9, rotates as illustrated in FIG. 16B.

FIG. 17A is a diagram illustrating a closed state of an example of the pressure-regulating valve having a double-doored configuration. FIG. 17B is a diagram illustrating an open state of the example of the pressure-regulating valve having the double-doored configuration.

For example, as illustrated in FIG. 17A, part of the blank panel 92 works as the pressure-regulating valve 9. This configuration is the same as that in FIG. 16A. In a case of the double-doored configuration, when the pressure in the cold aisle 51 is higher than the pressure in the hot aisle 52, the part of the blank panel 92, which is the pressure-regulating valve 9, separates into two at the center and rotates toward both sides, as illustrated in FIG. 17B. It is preferred that force is applied to the pressure-regulating valve 9 by an elastic member such as a spring to return the pressure-regulating valve 9 to the state in FIG. 17A.

### Modification

Next, as a modification of the third embodiment, described is a case in which the management server 10 controls the opening and closing of the pressure-regulating valve 9. FIG. 18 is a block diagram of a container-type data center according to the modification of the third embodiment.

The management server 10 in the container-type data center 100 according to the modification includes a valve control unit 104. For example, the valve control unit 104 stores therein standard pressure as the atmospheric pressure. The container-type data center 100 according to the modification includes a differential pressure sensor 81 that measures a differential pressure between the pressure in the cold aisle 51 and the pressure in the hot aisle, instead of the pressure sensor 8 in the first embodiment.

The valve control unit 104 receives an input of information about the pressure in the cold aisle 51 from the differential pressure sensor 81. Next, the valve control unit 104 determines whether the pressure in the cold aisle 51 is higher than the stored atmospheric pressure. If the pressure in the cold aisle 51 is higher than the atmospheric pressure, the valve control unit 104 opens the pressure-regulating valve 9.

After that, when the pressure in the cold aisle 51 has become equal to or less than the atmospheric pressure, the valve control unit 104 returns the pressure-regulating valve 9 to the original position to block the path connecting the cold aisle 51 and the hot aisle 52.

In the modification, the valve control unit 104 opens the pressure-regulating valve 9 when the pressure in the cold aisle 51 is higher than the atmospheric pressure. Alternatively, another criterion for opening may be used. For example, the valve control unit 104 may open the pressure-regulating valve 9 when the pressure in the cold aisle 51 is higher than the atmospheric pressure by a predetermined value. This prevents the pressure-regulating valve 9 from opening when the increase in the pressure in the cold aisle 51 is small.

Next, with reference to FIG. 19, described is the procedure of a process for adjusting pressure with the container-type data center according to the present embodiment. FIG. 19 is a flow chart of the process for adjusting pressure with the container-type data center according to the modification of the third embodiment. The process described below is the procedure of one process for adjusting the pressure. Practically, the management server 10 periodically repeats the procedure of the processes.

The shutter control unit 102 determines whether the air conditioner 3 has stopped based on a notification from the state monitoring unit 101 (Step S301). If the air conditioner 3 has stopped (Yes at Step S301), the shutter control unit 102 opens the shutter 60 and the shutter 70 (Step S302).

After that, the shutter control unit 102 determines whether the air conditioner 3 has resumed based on a notification from the state monitoring unit 101 (Step S303). If the air conditioner 3 has not resumed (No at Step S303), the shutter control unit 102 waits until the air conditioner 3 resumes.

If the air conditioner 3 has resumed (Yes at Step S303), the shutter control unit 102 closes the shutter 60 and the shutter 70 (Step S307).

If the air conditioner has not stopped (No at Step S301), the shutter control unit 102 determines whether the pressure in the cold aisle 51 is less than the atmospheric pressure (Step S304).

If the pressure in the cold aisle 51 is less than the atmospheric pressure (Yes at Step S304), the shutter control unit 102 opens the shutter 60 and the shutter 70 (Step S305).

After that, the shutter control unit 102 determines whether the pressure in the cold aisle 51 is equal to or more than the atmospheric pressure (Step S306). If the pressure in the cold aisle 51 is less than the atmospheric pressure (No at Step S306), the shutter control unit 102 waits until the pressure in the cold aisle 51 becomes equal to or more than the atmospheric pressure.

If the pressure in the cold aisle 51 is equal to or more than the atmospheric pressure (Yes at Step S306), the shutter control unit 102 closes the shutter 60 and the shutter 70 (Step S307).

If the pressure in the cold aisle 51 is equal to or more than the atmospheric pressure (No at Step S304), the valve control unit 104 determines whether the pressure in the cold aisle 51 is higher than the pressure in the hot aisle 52 (Step S308). If the pressure in the cold aisle 51 is equal to or less than the pressure in the hot aisle 52 (No at Step S308), the management server 10 finishes the process for adjusting the pressure.

If the pressure in the cold aisle 51 is higher than the pressure in the hot aisle 52 (Yes at Step S308), the valve control unit 104 opens the pressure-regulating valve 9 (Step S309).

After that, the valve control unit 104 determines whether the pressure in the cold aisle 51 has become equal to or less than the pressure in the hot aisle 52 (Step S310). If the pressure in the cold aisle 51 is higher than the pressure in the hot aisle 52 (No at Step S310), the valve control unit 104 waits until the pressure in the cold aisle 51 becomes equal to or less than the pressure in the hot aisle 52.

If the pressure in the cold aisle 51 is equal to or less than the pressure in the hot aisle 52 (Yes at Step S310), the valve control unit 104 closes the pressure-regulating valve 9 (Step S311).

As described above, the container-type data center according to the present embodiment allows connection between the cold aisle and the hot aisle when the pressure in the cold aisle is higher than the pressure in the hot aisle, in addition to the opening and closing of the shutters in the first embodiment. This eliminates a difference between the pressure in the cold aisle and the pressure in the hot aisle, and the pressure balance may be more appropriately maintained.

### [d] Fourth Embodiment

FIG. 20 is a schematic cross-sectional view of a container-type data center according to a fourth embodiment. The container-type data center 100 according to the present embodiment is a combination of the second embodiment and the third embodiment.

In FIG. 20, the management server 10 can control the air conditioner, and the pressure-regulating valve 9 is arranged. In such a case, the management server 10 lowers the volume of air when the pressure in the cold aisle 51 becomes higher than the atmospheric pressure. When the pressure in the cold aisle 51 becomes higher than the pressure in the hot aisle 52, the pressure-regulating valve 9 opens.

This has the effects of adjustment of the pressure balance in the first to the third embodiments, so that the pressure balance may be more appropriately maintained.

According to one aspect of the container-type data center and the method for controlling the container-type data center disclosed herein, the pressure balance in the container can be maintained.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A container-type data center comprising:
a container that includes electronic equipment mounted therein and separates a first area as an intake side of the electronic equipment from a second area as an exhaust side of the electronic equipment;
a first shutter that opens and closes an opening connecting outside and inside of the container provided in the first area;
a second shutter that opens and closes an opening connecting outside and inside of the container provided in the second area;
an air conditioning mechanism that cools air taken in from the second area and exhausts the air to the first area; and
a control unit that controls opening and closing of the first shutter and the second shutter based on an acquired pressure in the first area or an operating state of the air conditioning mechanism.

2. The container-type data center according to claim 1, wherein the control unit opens the first shutter and the second shutter when the air conditioning mechanism has stopped.

3. The container-type data center according to claim 2, wherein, in a state in which the first shutter and the second shutter are open because of the stoppage of the air conditioning mechanism, the control unit closes the first shutter and the second shutter when the air conditioning mechanism has resumed.

4. The container-type data center according to claim 1, wherein the control unit opens the first shutter and the second shutter when pressure in the first area is lower than atmospheric pressure.

5. The container-type data center according to claim 4, wherein, in a state in which the first shutter and the second shutter are open because the pressure in the first area is lower than the atmospheric pressure, the control unit closes the first shutter and the second shutter when the pressure in the first area has become equal to or more than the atmospheric pressure.

6. The container-type data center according to claim 1, wherein
the container includes a rack to which a plurality of pieces of electronic equipment are mounted, and
the rack includes, at a position where the electronic equipment is not mounted, a pressure-regulating valve that passes air when the pressure in the first area is higher than pressure in the second area by a predetermined value, and blocks air between the first area and the second area when the pressure in the first area is lower than the pressure in the second area by a predetermined value.

7. The container-type data center according to claim 6 further comprising:
a valve control unit that opens the pressure-regulating valve when the pressure in the first area is higher than the pressure in the second area by a predetermined value, and closes the pressure-regulating valve to separate the first area and the second area when the pressure in the first area is lower than the pressure in the second area by a predetermined value.

8. The container-type data center according to claims 1, wherein
the air conditioning mechanism includes a fan for sending air to the electronic equipment, and
the data center further comprises a fan control unit that controls to reduce rotational speed of the fan when the pressure in the first area is higher than that of outside air.

9. A method for controlling a container-type data center that comprises:
a container that includes electronic equipment mounted therein and separates a first area as an intake side of the electronic equipment from a second area as an exhaust side of the electronic equipment;
a first shutter that opens and closes an opening connecting outside and inside of the container provided in the first area;
a second shutter that opens and closes an opening connecting outside and inside of the container provided in the second area; and
an air conditioning mechanism that cools air taken in from the second area and exhausts the air to the first area, the method comprising:
acquiring any of pressure in the first area and an operating state of the air conditioning mechanism to control opening and closing of the first shutter and the second shutter based on any of the acquired pressure in the first area and the operating state of the air conditioning mechanism.
